(19) United States
(12) Patent Application Publication
(10) Pub. No.: US 2012/0319237 A1
(43) Pub. Date: Dec. 20, 2012

(54) CORNER-ROUNDED STRUCTURES AND METHODS OF MANUFACTURE

(75) Inventors: Edward C. COONEY, III, Jericho, VT (US); Jeffrey P. GAMBINO, Westford, VT (US); Zhong-Xiang HE, Essex Junction, VT (US); Thomas L. MCDEVITT, Underhill, VT (US); Gary L. MILO, Williston, VT (US)

(73) Assignee: INTERNATIONAL BUSINESS MACHINES CORPORATION, Armonk, NY (US)

(21) Appl. No.: 13/163,922

(22) Filed: Jun. 20, 2011

(51) Int. Cl. H01L 21/768; H01L 23/522

(52) U.S. Cl. 257/531; 438/618; 257/E21.575; 257/E23.142

(57) ABSTRACT

Corner-rounded structures and methods of manufacture are provided. The method includes forming at least two conductive wires with rounded corners on a substrate. The method further includes forming a insulator film on the substrate and between the at least two conductive wires with the rounded corners.

### FIELD OF THE INVENTION

The invention relates to semiconductor structures and methods of manufacture and, more particularly, to corner-rounded structures and methods of manufacture.

### BACKGROUND

The use of inductors is common in current integrated circuits. These integrated circuits include resonant circuits and “system-on-chip” circuits that integrate analog, digital, and passive devices on a semiconductor substrate. As performance requirements of semiconductor devices increase, and dimension requirements of such devices decrease, inductors also require greater performance and smaller dimensions.

However, such small inductors and other varying layers can become damaged during fabrication. For example, tight or close spacing (e.g., distances) between wires of an inductor may generate stress on dielectric material between the wires when these components are heated and expanded during thermal processes (e.g., when an oxide film is formed on the inductor). This generated stress may cause the dielectric material to crack, thus impairing the performance of the fabricated inductor.

Accordingly, there exists a need in the art to overcome the deficiencies and limitations described hereinabove.

### SUMMARY

In a first aspect of the invention, a method includes forming at least two conductive wires with rounded corners on a substrate. The method further includes forming a insulator film on the substrate and between the at least two conductive wires with the rounded corners.

In another aspect of the invention, a method includes forming two or more conductive wires with rounded corners on a wafer body. The rounded corners include at least one of outside rounded corners where outside edges of the two or more conductive wires meet, and inside rounded corners where inside edges of the two or more conductive wires meet. The method further includes forming a dielectric layer on the wafer body and between the two or more conductive wires.

In yet another aspect of the invention, a structure includes at least two conductive wires with rounded corners formed on a substrate. The structure also includes a dielectric film formed on the substrate and between the at least two conductive wires with the rounded corners, where the dielectric film is devoid or substantially devoid of cracking.

In another aspect of the invention, a design structure tangibly embodied in a machine readable storage medium for designing, manufacturing, or testing an integrated circuit is provided. The design structure comprises the structures of the present invention. In further embodiments, a hardware description language (HDL) design structure encoded on a machine-readable data storage medium comprises elements that when processed in a computer-aided design system generates a machine-executable representation of a corner-rounded structure, which comprises the structures of the present invention. In still further embodiments, a method in a computer-aided design system is provided for generating a functional design model of the corner-rounded structure. The method comprises generating a functional representation of the structural elements of the corner-rounded structure.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIGS. 1A-1D show fabrication steps and respective structures in accordance with aspects of the invention;

FIGS. 2A-2D show alternative fabrication steps and respective structures in accordance with aspects of the invention;

FIG. 3 shows an exemplary top view of a corner-rounded structure in accordance with aspects of the invention;

FIGS. 4A-4C show additional exemplary top views of corner-rounded structures in accordance with aspects of the invention;

FIG. 5A shows a top view of a semiconductor structure with a crack formation, fabricated using conventional processes;

FIG. 5B shows an exemplary top view of semiconductor structure in accordance with aspects of the invention;

FIG. 6 show an exemplary graph of crack impact of semiconductor structures with various mask radiuses in accordance with aspects of the invention; and

FIG. 7 is a flow diagram of a design process used in semiconductor design, manufacture, and/or test.

### DETAILED DESCRIPTION

The invention relates to semiconductor structures and methods of manufacture and, more particularly, to corner-rounded structures and methods of manufacture. More specifically, the present invention is directed to a semiconductor structure including at least two wires with rounded inside and/or outside corners. In embodiments, the wires can be an inductor, a coil structure, and/or any electrical component that may include the corner-rounded wires. In embodiments, the rounded corners of the wires may be formed by conventional processes, for example, lithography, etching, and deposition processes with optical proximity correction (OPC) processes. Advantageously, the rounded corners of the wires may prevent or eliminate cracking of dielectric material between the wires during thermal cycling.

More specifically, during the forming of a dielectric film, an oxide film, and/or a passivation (generally referred to as an insulator film) film on the semiconductor structure, temperatures of components (e.g., the wires) of the structure rise due to thermal cycles of these processes, and can expand. As the wires and the dielectric film have a coefficient of thermal expansion (CTE) mismatch (e.g., the CTE of the wires are different than the CTE of the dielectric film), the expanding wires cause stress on the insulator films. This stress may be generated from inside and outside corners of the wires where seams may be formed from the deposition of the insulator films, for example. The stress, in turns, results in cracking of insulator films (e.g., dielectric film, oxide film, passivation film, etc.) between the wires.

In embodiments, the rounded inside and/or outside corners of the wires prevent or eliminate this cracking of the insulator films between the wires during subsequent fabrication processes, e.g., deposition of insulator films, such as dielectric films, oxide films, and/or passivation films over the wiring layer. In particular, the rounded corners of the present invention minimize stress applied from the wires to the insulator films during subsequent temperature cycling due to the fabrication processes. In addition, the rounded corners eliminate the creation of seams during the dielectric and/or passivation film deposition.

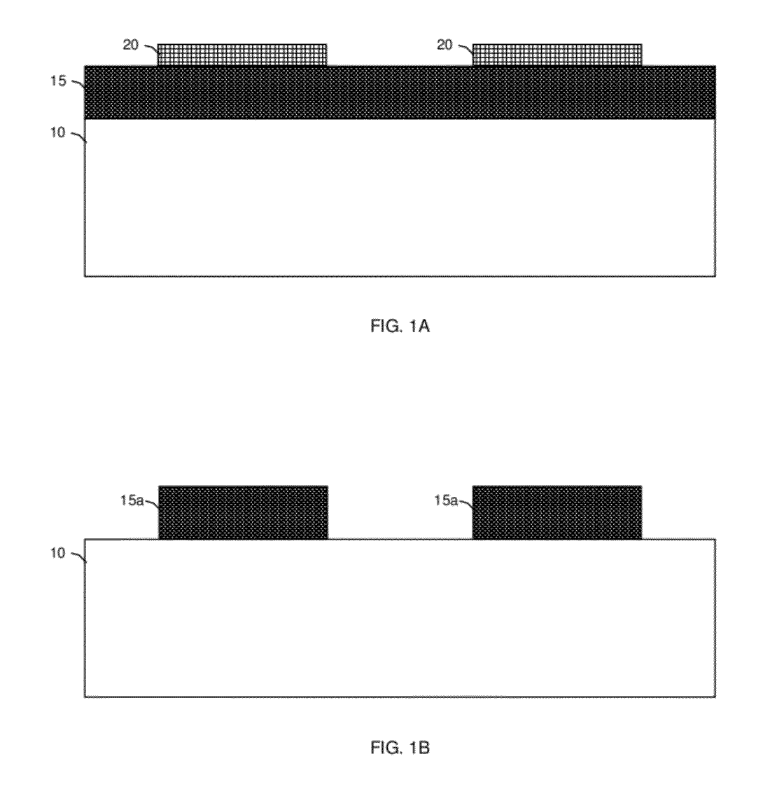

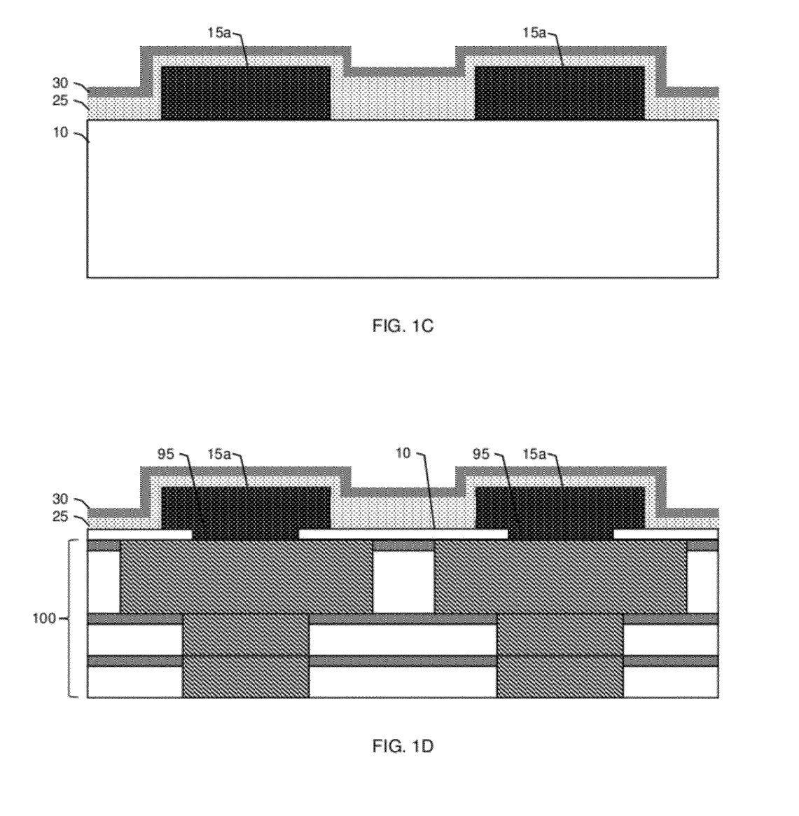

FIG. 1A shows a structure and respective fabrication processes in accordance with aspects of the invention. The structure includes a substrate 10 (e.g., a dielectric layer) that, in embodiments, can include any insulator film, such as silicon dioxide (SiO₂), carbon-doped silicon oxide (SiCOH), silicon carbide (SiC), etc. In embodiments, the substrate 10 can include contacts and/or wiring layers (as shown in FIG. 1D), which are connected to an upper and/or lower wiring layer. Accordingly, the substrate 10 (and resulting structure) can be provided on any metallization layer of a semiconductor structure. A conductive layer 15 is formed on the substrate 10, in physical contact with the substrate 10. In embodiments, the conductive layer 15 can include any conductive material, such as aluminum, copper, etc. The conductive layer 15 may be formed by conventional processes, for example, subtractive metal processes using optical proximity correction (OPC).

By way of example, the conductive layer 15 can be blanket deposited on the substrate 10 using conventional metal deposition processes. A mask (resist) 20 is formed on the conductive layer 15, which is exposed to energy, e.g., light, to form patterns with rounded corners. The rounded corners can be formed with conventional photolithography tools, using OPC. The rounded corners, as described below, are then transferred onto the conductive layer 15 to form wires 15a with rounded corners.

In FIG. 1B, exposed portions of the conductive layer are removed, e.g., etched, using a reactive ion etching (RIE) process. The etching process results in the wires or wiring pattern 15a on the substrate 10. The wires 15a includes wires with rounded corners, on inside and/or outside corners. Advantageously, the rounded corners of the wires 15a prevent or eliminate cracking of insulator material between and below the wires 15a that may be formed during subsequent thermal processes, i.e., deposition of insulator material. The mask 20 is removed using, for example, conventional ashing processes. In one illustrative, non-limiting example, each of the wires 15a may have a width of about 5 μm-200 μm. The wires 15a may be separated by a distance of about 5 μm-200 nm, and even more specifically about 5 μm-30 μm; although other distances are contemplated by the invention. The rounded corners can have a radius, for example, of about 10% to 50% of the width of the wires 15a and more preferably about 10% to 20% of the width of the wires 15a; although other rounded corner dimensions are contemplated by the present invention. For example, a 5 μm offset rounded feature has been shown to alleviate stresses, regardless of wire width.

In FIG. 1C, one or more insulator films are formed on the substrate 10 and the wires 15a using, for example, conventional deposition processes. For example, in embodiments, an oxide film 25 is formed in physical contact on the substrate 10 and the wires 15a. The oxide film 25 may include, for example, a tetraethoxysilane (TEOS) oxide material, deposited using conventional deposition processes, such as chemical vapor deposition (CVD). The depth of the oxide film 25 can vary, depending on the particular design parameters. In one non-limiting illustrative example, the oxide film 25 can be deposited to a depth of about 1.5 microns. A passivation layer 30 is formed in physical contact with the oxide film 25. The passivation layer 30 may include any dielectric material, for example, a silicon nitride. The depth of the passivation layer 30 can vary, depending on the particular design parameters. In one non-limiting illustrative example, the passivation layer 30 can be deposited to a depth of about 0.5 microns. In embodiments, the insulator films may be other films known to those of skill in the art such as, for example, SiO₂, SICOH and/or SiC. The structure of FIG. 1C may be, for example, an inductor, a coil structure, and/or any electrical component that may include wires, e.g., the wires 15a.

Still referring to FIG. 1C, it should be understood by those of ordinary skill in the art that the wires 15a and the insulator films have different coefficients of thermal expansions (CTEs). This being the case, during the formation of the insulator films, the structure undergoes a temperature change, e.g., heating and cooling, which causes the wires 15a and the insulator layer(s) to expand and contract at different rates. These different expansion and contraction rates result in stress being imposed on the structure, typically generated from inside and outside corners of the wires 15a where, in conventional structures, seams are formed resulting in cracks or other defects of the structure. That is, in conventional structures, this stress results in cracking of dielectric material (e.g., the insulator films, the substrate 10, etc.) between and below the wires 15a. The cracking may be more prevalent when the wires 15a are in close proximity to each other, e.g., spacing of about 5 μm-10 μm. The amount of cracking of the insulator films may also be greater as a ratio of the width of the wires 15a over the width of the insulator films between the wires 15a, is greater. However, the rounded corners of the wires 15a prevent or eliminate cracking of the dielectric material and/or other insulator layers between and below the wires 15a, as it significantly reduces stresses imposed by the expansion and contraction of the wires 15a. That is, the rounded corners alleviate or minimize stresses imposed on the insulator films, thereby eliminating the cracking.

FIG. 1D shows a structure and respective fabrication processes in accordance with aspects of the invention. The structure includes several wiring layers (metallization layers including, for example, the structure shown in FIG. 1C, as a top layer). More specifically, the structure includes the wires 15a formed on the substrate 10. The substrate 10, i.e., dielectric film, includes interconnects 95 connecting to underlying metallization layers generally shown as reference numeral 100. The interconnects 95 can be formed using, for example, a tapered via process.

In embodiments, the metallization layers 100 can include wires separated from each other by dielectric or other insulator material therebetween. The wires of the metallization layers 100 may include any conductive material, such as copper, aluminum, etc. The dielectric or other insulator material of the metallization layers 100 may include any insulator material, such as silicon dioxide, carbon-doped silicon oxide, silicon carbide, silicon nitride, etc. In embodiments, the insulator layers on different metallization layers can be separated from one another by a nitride based material, e.g., SiN. The metallization layers 100 may be formed by conventional processes, e.g., damascene processes, as understood by those of ordinary skill in the art. In embodiments, the wires of the metallization layers 100 and the wires 15a can include rounded corners as discussed above. By implementing the rounded corners, cracking and other defects in the underlying insulator layers, i.e., dielectric layers, of the metallization layers 100 can be eliminated.

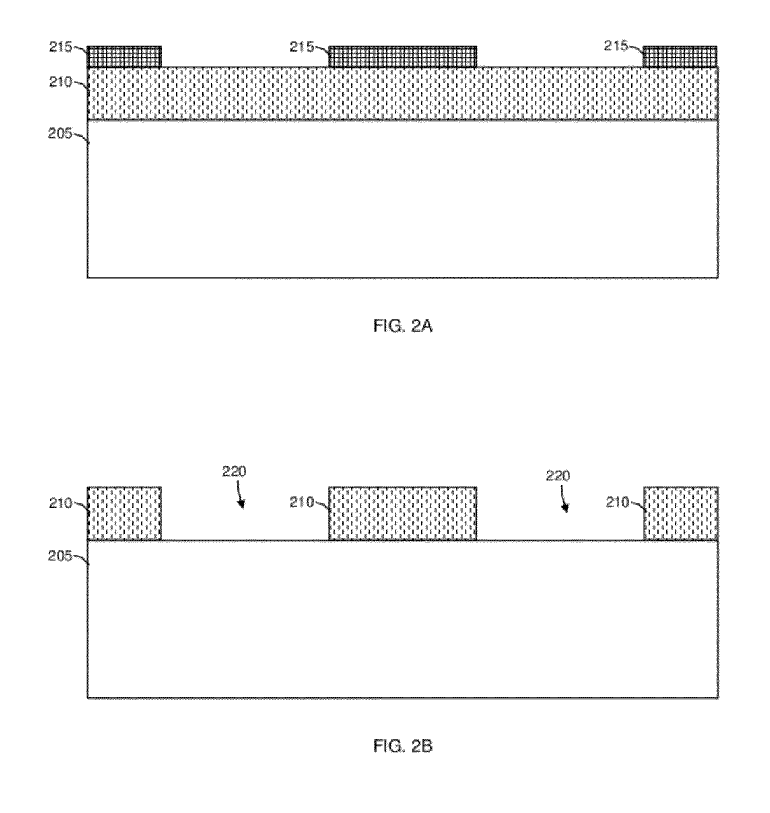

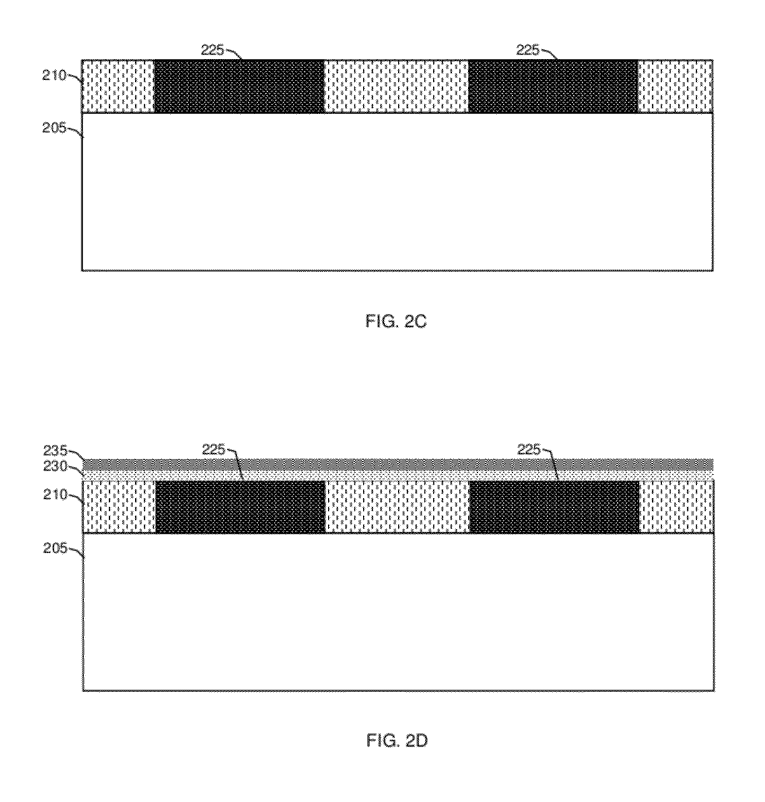

FIG. 2A shows a structure and respective fabrication processes in accordance with aspects of the invention. The structure includes a substrate 205 (e.g., a wafer body) that, in embodiments, can include any insulator material such as, for example, SiO₂, SICOH, SiC, etc. A dielectric layer 210 is formed in physical contact on the substrate 205. In embodiments, the dielectric layer 210 can include any dielectric or insulator material, such as silicon dioxide, carbon-doped silicon oxide, silicon carbide, etc. The dielectric layer 210 may be deposited by a conventional CVD process. A mask (resist) 215 is formed on the dielectric layer 210, and patterned by exposing it to energy, i.e., light. The pattern of the mask 215 is shaped to include rounded corners.

In FIG. 2B, the exposed portions of the dielectric layer 210 are removed, e.g., etched, using a RIE process, to form trenches 220 through the dielectric layer 210. The trenches 220 will have the rounded corners, transferred from the mask 215. The mask 215 is then removed using conventional ashing processing, leaving previously-covered portions of the dielectric layer 210. In one illustrative, non-limiting example, each of the trenches 220 may have a width of about 5 μm-200 μm. The trenches 220 may be separated by a distance of about 5 μm-200 nm, and more specifically, 5 μm-30 μm; although other ranges are contemplated by the invention. As noted above, in embodiments, due to the shape of the mask 215, the trenches 220 may include rounded corners where edges of the trenches 220 meet.

In FIG. 2C, wires 225 are formed in the trenches 220 by a conventional metal deposition process. In embodiments, the wires 225 can include any conductive material, such as aluminum, copper, etc. The rounded corners of the trenches 220 will be transferred to the wires 225. The rounded corners of the wires 225 can have a radius, for example, of about 10% to 50% of the width of the wires 15a and more preferably about 10% to 20% of the width of the wires 15a; although other rounded corner dimensions are contemplated by the present invention. For example, a 5 μm offset rounded feature has been shown to alleviate stresses, regardless of wire width.

The surface of the structure may then be planarized using a chemical mechanical polishing (CMP). In one illustrative, non-limiting example, each of the wires 225 may have a width of about 5 μm-200 μm. The wires 225 may be separated by the dielectric layer 210 between the wires 225. This results in a spacing between the wires 225 of about 5 μm-200 nm, and more specifically, 5 μm-30 μm; although other ranges are contemplated by the invention. Due to the shape of the mask 215, the wires 225 may include rounded corners. Advantageously, the rounded corners of the wires 225 prevent or eliminate cracking of dielectric or other insulator material (e.g., the dielectric layer 210, etc.) between and below the wires 225, which would otherwise form during subsequent processes.

In FIG. 2D, an insulator layer 230, e.g., oxide, is formed on the structure, in physical contact with the dielectric layer 210 and the wires 225. The oxide layer 230 can include, for example, a tetraethoxysilane (TEOS) oxide material. A passivation layer 235 is formed on the structure, in physical contact with the oxide layer 230. The passivation layer 235 may include any dielectric material, for example, a silicon nitride. The structure of FIG. 2D may be, for example, an inductor, a coil structure, and/or any electrical component that may include corner-rounded wires, e.g., the wires 225. As noted above, the rounded corners of the wires 225 prevent or eliminate cracking of the dielectric material between and below the wires 225, which would otherwise result from thermal cycling during the forming of the oxide layer 230 and/or the passivation layer 235.

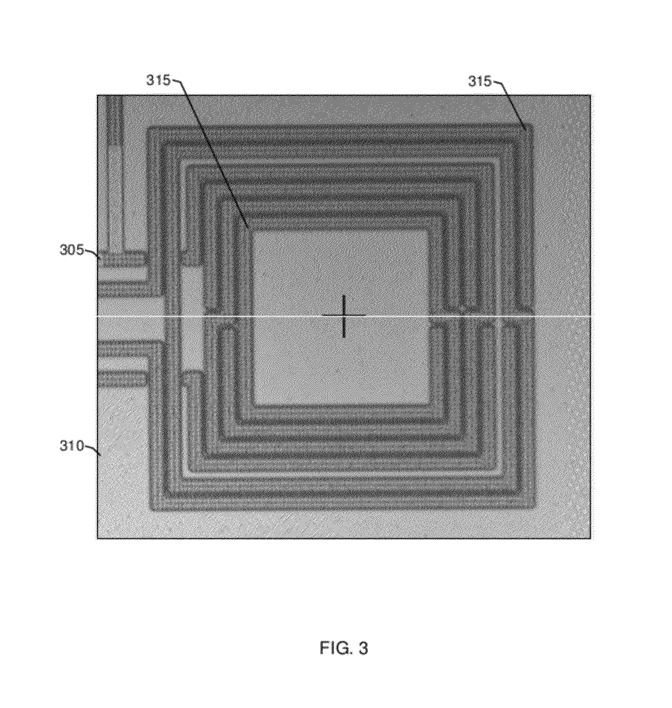

FIG. 3 shows an exemplary top view of a corner-rounded structure in accordance with aspects of the invention. In embodiments, the structure can be, for example, an inductor, a coil structure, and/or any electrical component that may include wires. More specifically, the structure includes at least two wires 305 and a dielectric or other insulator film 310. In embodiments, the wires 305 may include any conductive material (e.g., aluminum and/or copper), and the dielectric or other insulator film 310 may include any dielectric material (e.g., silicon dioxide, carbon-doped silicon oxide, and/or silicon carbide). In one illustrative, non-limiting example, each of the wires 305 may have a width within a range of 5 μm-200 μm and/or within a range conventional to one of ordinary skill in the art. The wires 305 may be separated by a distance within a range of 5 μm-200 nm, more specifically, 5 μm-30 μm, although other ranges are contemplated by the invention. In other words, the insulator film 310 may include a width between the wires 305 within a range of 5 μm-200 nm, more specifically, 5 μm-30 μm, although other ranges are contemplated by the invention.

Still referring to FIG. 3, the wires 305 include rounded corners 315 where edges of the wires 305 meet. That is, the rounded corners 315 can be inside and outside rounded corners, formed at jogs of the wires. In embodiments, the rounded corners 315 can be formed, for example, through a shape of a lithographic mask used to form the wires 305, through conventional optical proximity correction (OPC) processes as described above. The rounded corners 315 prevent or eliminate cracking in the dielectric or other insulator film 310, which would otherwise result due to a coefficient of thermal expansion (CTE) mismatch between the dielectric or other insulator film 310 and the wires 305 during fabrication of the structure. As shown here, there is no cracking in the dielectric film 310 due to the rounded corners 315 since less stress is applied from the wires 305 to the dielectric or other insulator film 310.

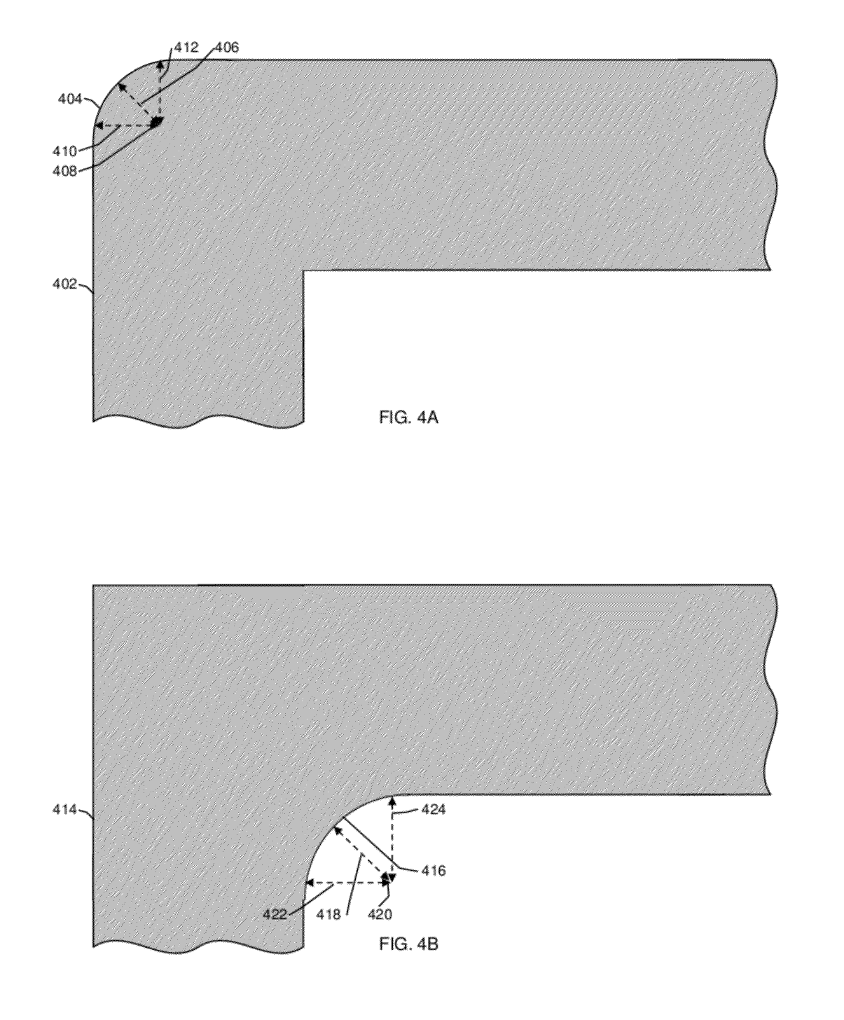

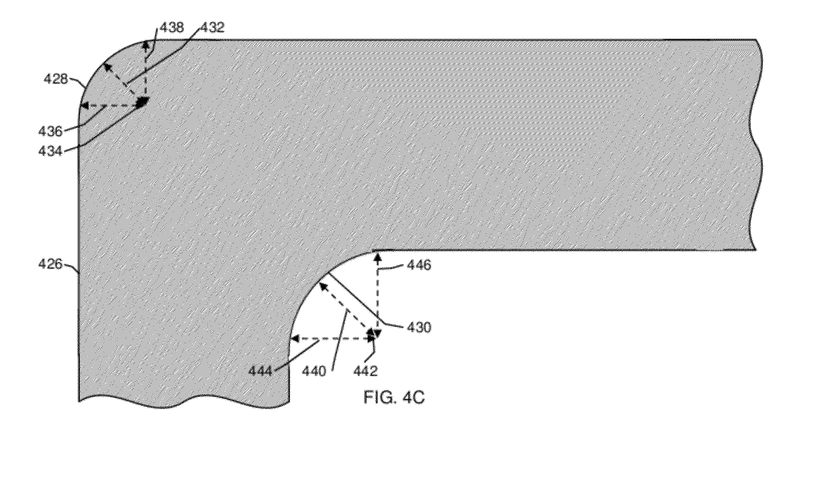

FIG. 4A shows an exemplary top view of a corner-rounded structure in accordance with aspects of the invention. More specifically, the structure includes a wire 402, which can include any conductive material, e.g., aluminum and/or copper. In one illustrative, non-limiting example, the wire 402 can have a width of about 10 μm-20 μm. The wire 402 includes an outside rounded corner 404 to prevent or eliminate cracking of dielectric material adjacent to the wire 402. In embodiments, the outside rounded corner 404 may include a radius of curvature 406 of about 1 μm-10 μm, and even more specifically, of about 2 μm-8 μm, with an optimal value of 5 μm; although other values are contemplated by the invention. The radius of curvature 406 is a distance of the outside rounded corner 404 from a point 408, which is distances 410 and 412 away from respective outside edges of the wire 402. In embodiments, each of the distances 410, 412 may be equal to the radius of curvature 406, e.g., 5 μm. In additional embodiments, the radius of curvature 406 may be at least about 10% of the width of the wire 402. The above dimensions (e.g., the width of the wire 402, the radius of curvature 406, etc.) may be necessary to prevent or eliminate cracking of the dielectric material when a spacing or distance between the wire 402 and another wire is about 5 μm-20 μm. For larger wires (e.g., 100 μm or larger) in close spacing (e.g., 5 μm-20 μm), a radius of curvature of an outside rounded corner of a larger wire may be about 2 μm-5 μm, to prevent or eliminate cracking of dielectric material adjacent to the larger wires.

FIG. 4B shows an exemplary top view of another corner-rounded structure in accordance with aspects of the invention. More specifically, the structure includes a wire 414, which can include any conductive material, e.g., aluminum and/or copper. In one illustrative, non-limiting example, the wire 414 can have a width of about 10 μm-20 μm. The wire 414 includes an inside rounded corner 416 to prevent or eliminate cracking of dielectric material adjacent to the wire 414. In embodiments, the inside rounded corner 416 may include a radius of curvature 418 of about 1 μm-10 μm, even more specifically, of about 2 μm-8 μm, and with an optimal value of 5 μm; although other values are contemplated by the invention. The radius of curvature 418 is a distance of the inside rounded corner 416 from a point 420, which is distances 422 and 424 away from respective inner edges of the wire 414. In embodiments, each of the distances 422, 424 may be equal to the radius of curvature 418, e.g., 5 μm. In additional embodiments, the radius of curvature 418 may be at least about 10% of the width of the wire 414. The above dimensions (e.g., the width of the wire 414, the radius of curvature 418, etc.) may be necessary to prevent or eliminate cracking of the dielectric material when a spacing or distance between the wire 414 and another wire is about 5 μm-20 μm. For larger wires (e.g., 100 μm or larger) in close spacing (e.g., 5 μm-20 μm), a radius of curvature of an inside rounded corner of a larger wire may be about 2 μm-5 μm, to prevent or eliminate cracking of dielectric material adjacent to the larger wires.

FIG. 4C shows an exemplary top view of another corner-rounded structure in accordance with aspects of the invention. More specifically, the structure includes a wire 426, which can include any conductive material, e.g., aluminum and/or copper. In one illustrative, non-limiting example, the wire 426 can have a width of about 10 μm-20 μm. The wire 426 includes an outside rounded corner 428 and an inside rounded corner 430 to prevent or eliminate cracking of dielectric material adjacent to the wire 426. In embodiments, the outside rounded corner 428 may include a radius of curvature 432 of about 1 μm-10 μm, even more specifically, of about 2 μm-8 μm, and with an optimal value of 5 μm; although other values are contemplated by the invention. The radius of curvature 432 is a distance of the outside rounded corner 428 from a point 434, which is distances 436 and 438 away from respective outside edges of the wire 426. In embodiments, each of the distances 436, 438 may be equal to the radius of curvature 432, e.g., 5 μm. In additional embodiments, the radius of curvature 432 may be at least about 10% of the width of the wire 426.

In embodiments, the inside rounded corner 430 may include a radius of curvature 440 of about 1 μm-10 μm, even more specifically, of about 2 μm-8 μm, and with an optimal value of 5 μm; although other values are contemplated by the invention. The radius of curvature 440 is a distance of the inside rounded corner 430 from a point 442, which is distances 444 and 446 away from respective outside edges of the wire 426. In embodiments, each of the distances 444, 446 may be equal to the radius of curvature 440, e.g., 5 μm. In additional embodiments, the radius of curvature 440 may be at least about 10% of the width of the wire 426. The above dimensions (e.g., the width of the wire 426, the radius of curvature 432, the radius of curvature 440, etc.) may be necessary to prevent or eliminate cracking of the dielectric material when a spacing or distance between the wire 426 and another wire is about 5 μm-20 μm. For larger wires (e.g., 100 μm or larger) in close spacing (e.g., 5 μm-20 μm), a radius of curvature of an outside rounded corner and/or an inside rounded corner of a larger wire may be about 2 μm-5 μm, to prevent or eliminate cracking of dielectric material adjacent to the larger wires.

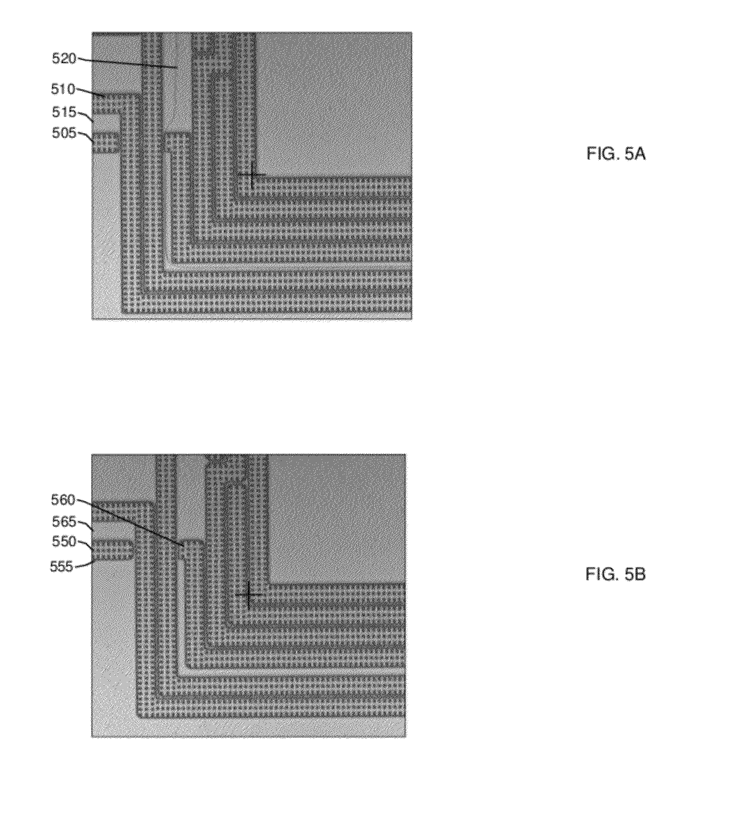

FIG. 5A shows a top view of a semiconductor structure fabricated using conventional processes. As described in more detail below, the semiconductor structure of FIG. 5A shows a crack formation due to CTE mismatch of materials. More specifically, the structure can be, for example, an inductor, a coil structure, and/or any electrical component that may include wires. The structure includes at least two wires 505, which may include any conductive material, e.g., aluminum and/or copper. In embodiments, the wires 505 may include vias 510 formed from a surface of the structure, through a top layer of the structure that includes the wires 505, to a lower layer of the structure that includes other (copper and/or aluminum) wires.

Still referring to FIG. 5A, the structure further includes a dielectric film 515, which can include any dielectric material, e.g., silicon dioxide, carbon-doped silicon oxide, and/or silicon carbide. In embodiments, spacing between the wires 505 (or a width of portions of the dielectric film 515 between the wires 505) may be about 5 μm-20 μm; although other values are contemplated by the invention. Further, in this structure, there is a coefficient of thermal expansion (CTE) mismatch between the wires 505 and the dielectric film 515. In these cases, when there is a temperature increase due to, for example, a formation of oxide and/or passivation films on the structure, the wires 505 and the dielectric film 515 may expand, resulting in a crack 520 in the dielectric film 515.

FIG. 5C shows an exemplary top view of a corner-rounded structure in accordance with aspects of the invention. As described herein, the structure shown in FIG. 5C is devoid of any cracks due to the corner rounding, i.e., which minimizes stresses on the structure. More specifically, the structure can be, for example, an inductor, a coil structure, and/or any electrical component that may include wires. The structure includes at least two wires 550, which may include any conductive material, e.g., aluminum and/or copper. In embodiments, the wires 550 may include vias 555 formed from a surface of the structure, through a top layer of the structure that includes the wires 550, to a lower layer of the structure that includes other (copper and/or aluminum) wires. The wires 550 may further include outside and/or inside rounded corners 560 where edges of the wires 550 meet. The rounded corners 560 include a radius of curvature of 5 μm; although other values are contemplated by the invention.

Still referring to FIG. 5C, the structure further includes a dielectric film 565, which can include any dielectric material, e.g., silicon dioxide, carbon-doped silicon oxide, and/or silicon carbide. When there is a temperature change due to, for example, a formation of oxide and/or passivation layers on the structure, the wires 550 and the dielectric film 565 may expand and then contract. However, due to the wires 550 having the rounded corners 560 with the radius of curvature of 5 μm, there is no crack in the dielectric film 565 since stress is minimized from the wires 550 to the dielectric film 565.

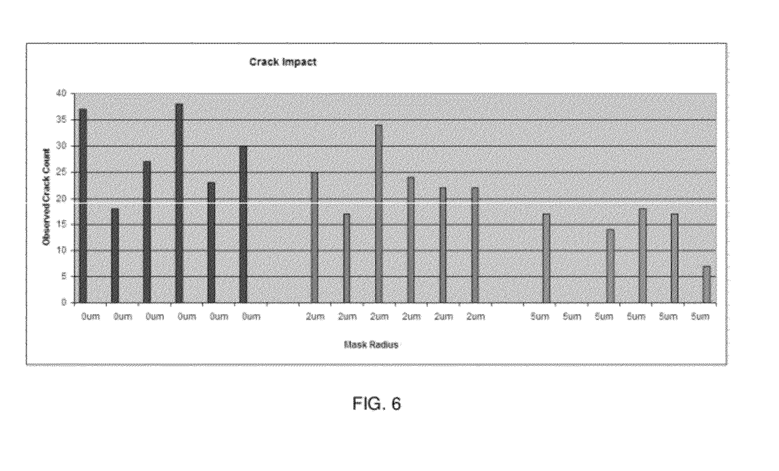

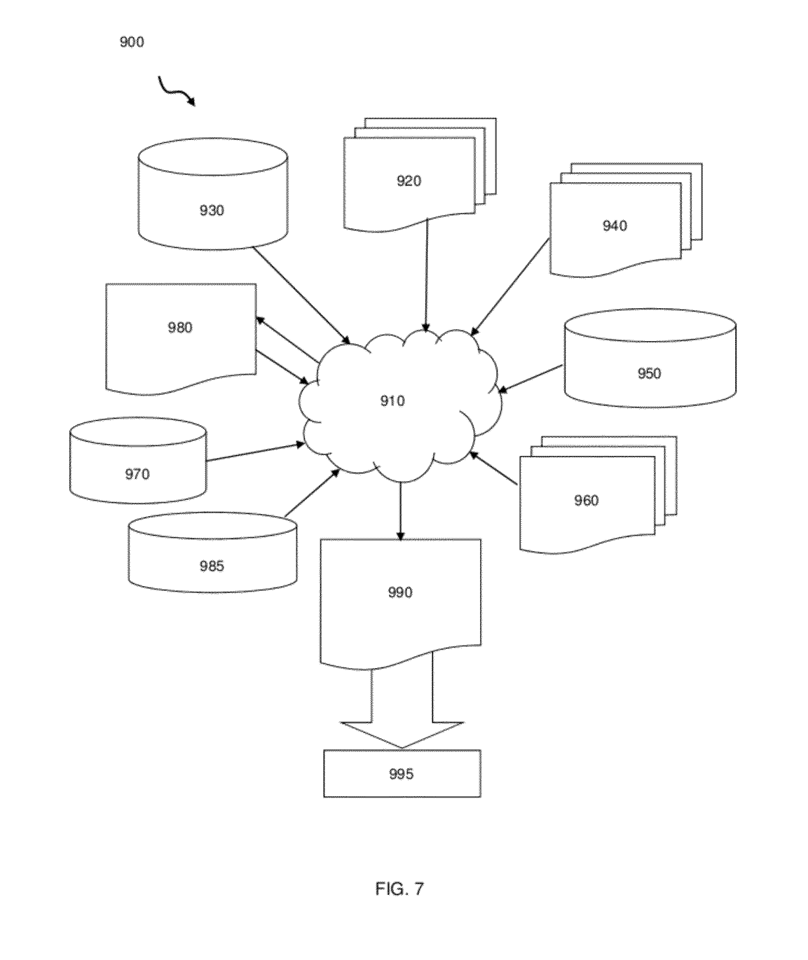

FIG. 6 show an exemplary graph of crack impact of semiconductor structures with various mask radiuses in accordance with aspects of the invention. More specifically, the graph includes observed crack counts (e.g., numbers of cracks in dielectric material between wires) for different semiconductor structures with varying mask radiuses (e.g., radiuses of curvature of rounded corners of wires in the semiconductor structures). For example, the first six semiconductor structures from the left of the graph include wires without rounded corners. These semiconductor structures have high observed crack counts, ranging from approximately 18 counts up to 38 counts. The next six semiconductor structures of the graph include wires with inside and/or outside rounded corners, each having a 2 μm radius of curvature. Due to the 2 μm rounded corners, these semiconductor structures have lower observed crack counts, ranging from approximately 17 counts up to 34 counts. The final six semiconductor structures from the left of the graph include wires with inside and/or outside rounded corners, each having a 5 μm radius of curvature. Due to the 5 μm rounded corners, these semiconductor structures have lower observed crack counts than the previous semiconductor structures, ranging from approximately 0 counts to 18 counts. Overall, the semiconductor structures with the 5 μm rounded corners have approximately 50% lower crack counts than the semiconductor structures without rounded corners or with the 2 μm rounded corners. Advantageously, rounded corners of wires in semiconductor structures can minimize or eliminate cracking of dielectric material between the wires by decreasing thermal stresses between the wires and the dielectric material.

FIG. 7 is a flow diagram of a design process used in semiconductor design, manufacture, and/or test. FIG. 7 shows a block diagram of an exemplary design flow 900 used for example, in semiconductor IC logic design, simulation, test, layout, and manufacture. Design flow 900 includes processes, machines and/or mechanisms for processing design structures or devices to generate logically or otherwise functionally equivalent representations of the design structures and/or devices described above and shown in FIGS. 1-5. The design structures processed and/or generated by design flow 900 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Altera® Inc. or Xilinx® Inc.

FIG. 7 illustrates multiple such design structures including an input design structure 920 that is preferably processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as those shown in FIGS. 1-5. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIGS. 1-5 to generate a netlist 980 which may contain design structures such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990.

Design structure 990 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-5. In one embodiment, design structure 990 may comprise a compiled, executable HDL simulation model that functionally simulates the devices shown in FIGS. 1-5.

Design structure 990 may also employ a data format used for the exchange of layout data of integrated circuits and/or symbolic data format (e.g. information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-5. Design structure 990 may then proceed to a stage 995 where, for example, design structure 990: proceeds to tape-out, is released to manufacturing, is released to a mask house, is sent to another design house, is sent back to the customer, etc.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims, if applicable, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principals of the invention and the practical application, and to enable others of ordinary skill in the art to understand the invention for various embodiments with various modifications as are suited to the particular use contemplated. Accordingly, while the invention has been described in terms of embodiments, those of skill in the art will recognize that the invention can be practiced with modifications and in the spirit and scope of the appended claims.

What is claimed:

1. A method, comprising:
forming at least two conductive wires with rounded corners on a substrate; and
forming a insulator film on the substrate and between the at least two conductive wires with the rounded corners.

2. The method of claim 1, wherein the at least two conductive wires comprise at least one of aluminum and copper.

3. The method of claim 1, wherein a distance between the at least two conductive wires is within a range of 5 μm-200 nm, with the insulator film therebetween.

4. The method of claim 3, wherein the distance between the at least two conductive wires is within a range of 5 μm-30 μm, with the insulator film therebetween.

5. The method of claim 1, wherein a width of each of the at least two conductive wires is within a range of 5 μm-200 μm.

6. The method of claim 1, wherein the rounded corners comprise outside rounded corners where outside edges of the at least two conductive wires meet.

7. The method of claim 1, wherein the rounded corners comprise inside rounded corners where inside edges of the at least two conductive wires meet.

8. The method of claim 1, wherein the rounded corners comprise:
outside rounded corners where outside edges of the at least two conductive wires meet; and
inside rounded corners where inside edges of the at least two conductive wires meet.

9. The method of claim 1, wherein a radius of curvature of each of the rounded corners is within a range of 1 μm-10 μm.

10. The method of claim 9, wherein the radius of curvature of each of the rounded corners is within a range of 2 μm-8 μm.

11. The method of claim 10, wherein the radius of curvature of each of the rounded corners is 5 μm.

12. The method of claim 1, wherein a radius of curvature of each of the rounded corners is about 10% of a width of each of the at least two conductive wires to a maximum wire width of 100 microns.

13. The method of claim 1, wherein the rounded corners are formed by one of subtractive metallization processes and damascene processes, with optical proximity correction (OPC) processes.

14. The method of claim 1, wherein the insulator film comprises of at least one of silicon dioxide (SiO₂), carbon-doped silicon oxide (SiCOH), and silicon carbide.

15. The method of claim 1, wherein the insulator film comprises:
forming an oxide film on the insulator film and the at least two conductive wires with the rounded corners; and
forming a passivation layer on the insulator film and the oxide film.

16. The method of claim 1, wherein:
the substrate comprises one or more interconnects connected to the at least two conductive wires; and
the method further comprises forming the substrate on one or more underlying metallization layers, each of the one or more underlying metallization layers comprising:
one or more corner-rounded wires and connected to the one or more interconnects; and
a dielectric film formed between the one or more corner-rounded wires.

17. A method comprising:
forming two or more conductive wires with rounded corners on a wafer body, the rounded corners comprising at least one of:
outside rounded corners where outside edges of the two or more conductive wires meet; and
inside rounded corners where inside edges of the two or more conductive wires meet; and
forming a dielectric layer on the wafer body and between the two or more conductive wires.

18. The method of claim 17, wherein:
a distance between the two or more conductive wires is within a range of 5 μm-30 μm, with the dielectric layer therebetween;
a width of each of the two or more conductive wires is within a range of 5 μm-200 μm; and
a radius of curvature of each of the rounded corners is 5 μm.

19. A structure, comprising
at least two conductive wires with rounded corners formed on a substrate; and
a dielectric film formed on the substrate and between the at least two conductive wires with the rounded corners, wherein the dielectric film is devoid or substantially devoid of cracking.

20. The structure of claim 19, wherein: the at least two conductive wires comprise at least one of aluminum and copper;
a distance between the at least two conductive wires is within a range of 5 μm-30 μm, with the dielectric film therebetween;
a width of each of the at least two conductive wires is within a range of 5 μm-200 μm;
a radius of curvature of each of the rounded corners is 5 μm; and
the dielectric film comprises of at least one of silicon dioxide (SiO₂), carbon-doped silicon oxide (SiCOH), and silicon carbide.
